(19) United States
(12) Patent Application Publication
(10) Pub. No.: US 2013/0192367 A1
(43) Pub. Date: Aug. 1, 2013

(54) VIBRATOR ELEMENT, VIBRATING DEVICE, PHYSICAL QUANTITY DETECTING DEVICE, AND ELECTRONIC APPARATUS

(71) Applicant: Seiko Epson Corporation, Tokyo (JP)

(72) Inventors: Seiji OSAWA, Minowa (JP); Masayuki KIKUSHIMA, Ina (JP); Takayuki KIKUCHI, Okaya (JP); Keiichi YAMAGUCHI, Ina (JP); Yuichi ISONO, Azumino (JP)

(73) Assignee: SEIKO EPSON CORPORATION, Tokyo (JP)

(21) Appl. No.: 13/750,033

(22) Filed: Jan. 25, 2013

(30) Foreign Application Priority Data
Jan. 30, 2012 (JP) 2012-016390

(51) Int. Cl. H01L 41/107

(52) U.S. Cl. CPC H01L 41/107; G01P 9/04
USPC 73/504.12; 310/367

(57) ABSTRACT

A first support portion, which is connected to a first beam extending from a vibrating body and supports the vibrating body, and a detection signal terminal and a detection ground terminal, which are provided in the first support portion and are arranged in parallel so as to be separated from each other along a direction crossing an extending direction of the first beam, are provided. The first beam and the first support portion are connected between the detection signal terminal and the detection ground terminal. A thin portion formed to have a small thickness in a top to bottom direction of the first support portion or a penetrating portion formed by removing the first support portion so as to be penetrated in the top to bottom direction is provided between the detection signal terminal and the detection ground terminal.

### BACKGROUND

1. Technical Field

The present invention relates to a vibrator element, a vibrating device, a physical quantity detecting device, and an electronic apparatus using these.

2. Related Art

As a vibrator element for detecting the angular velocity, a so-called “WT type” gyro element is known (for example, refer to JP-A-2006-201011 and JP-A-2010-256332).

A gyro element disclosed in JP-A-2006-201011 will be described as an example. The gyro element disclosed in JP-A-2006-201011 includes a vibrating body, first and second support portions that support the vibrating body, first and second beams that connect the vibrating body and the first support portion to each other, and third and fourth beams that connect the vibrating body and the second support portion to each other. In addition, the vibrating body includes a base portion, first and second detection vibrating arms extending from the base portion to both sides along the y axis, first and second connecting arms extending from the base portion to both sides along the x axis, first and second drive vibrating arms extending from the distal end of the first connecting arm to both sides along the y axis, and third and fourth drive vibrating arms extending from the distal end of the second connecting arm to both sides along the y axis.

Such a gyro element disclosed in JP-A-2006-201011 is mounted on a mounting substrate with a conductive adhesive interposed therebetween. Specifically, six connection terminals (fixing portions) provided in the first and second support portions and the mounting substrate are bonded using a conductive adhesive. As a result, the gyro element is fixed to the mounting substrate, and the gyro element and the mounting substrate are electrically connected to each other.

In the above-described gyro element, the occurrence of a so-called “vibration leakage phenomenon” is known in which the vibration of each drive vibrating arm or detection vibrating arm propagates to each beam, which is provided so as to extend from the vibrating body, and further propagates to the first and second support portions. If there is a vibration leakage phenomenon, when the connection terminal (fixing portion) is fixed to the mounting substrate, a vibration that is propagated is interrupted due to the vibration leakage phenomenon. This vibration interruption may also affect the vibration of the drive vibrating arm or the detection vibrating arm.

In addition, when the vibration of the drive vibrating armor the detection vibrating arm is also affected due to the vibration leakage phenomenon, the vibration characteristic of the gyro element deteriorates. In particular, a temperature drift is increased.

### SUMMARY

An advantage of some aspects of the invention is to solve at least a part of the problems described above, and the invention can be implemented as the following forms or application examples.

### APPLICATION EXAMPLE 1

This application example is directed to a vibrator element including: a vibrating body; a support portion that is connected to a beam extending from the vibrating body and that supports the vibrating body; and at least two fixing portions that are provided in the support portion and that are arranged in parallel so as to be separated from each other along a direction crossing an extending direction of the beam. The beam and the support portion are connected between the two fixing portions. A thin portion formed to have a thickness in a top to bottom direction of the support portion, which is smaller than a thickness of a portion in which the fixing portions of the support portion are provided, or a penetrating portion, which is formed by removing the support portion so as to be penetrated in the top to bottom direction, is provided between the two fixing portions.

In the vibrator element according to this application example, the beam is connected to at least the two fixing portions arranged in parallel so as to be separated from each other. In addition, the thin portion formed to have a small thickness in the top to bottom direction of the support portion or the penetrating portion formed by removing the support portion so as to be penetrated in the top to bottom direction is provided between the two fixing portions. Since the rigidity of a portion at which the beam and the support portion are connected becomes weak due to the thin portion and the penetrating portion, deformation easily occurs. By deformation of this portion, it is possible to reduce the stress of the beam. Accordingly, since stress generated over the range from the vibrating body to the beam can be reduced, it is possible to reduce the propagation of a vibration caused by the vibration leakage phenomenon, which propagates to the beam, to the fixing portion. As a result, it is possible to provide a vibrator element capable of reducing the deterioration of the vibration characteristic, especially, reducing a temperature drift.

### APPLICATION EXAMPLE 2

This application example is directed to the vibrator element according to the above-described application example, wherein the support portion includes a narrow portion which extends from the beam to each of the two fixing portions and in which a width of the support portion is smaller than a width of the portion in which the fixing portions of the support portion are provided.

In the vibrator element according to this application example, the narrow portion extending from the beam to the two fixing portions is provided. Accordingly, through the narrow portion that is easily deformed due to its small width, it is possible to reduce the stress generated over the range from the vibrating body to the beam. As a result, it is possible to reduce the propagation of a vibration caused by the vibration leakage phenomenon, which propagates to the beam, to the two fixing portions.

### APPLICATION EXAMPLE 3

This application example is directed to the vibrator element according to the above-described application example, wherein an end of the thin portion or the penetrating portion facing the vibrating body is opened on a side surface of the support portion.

In the vibrator element according to this application example, the beam and the narrow portion formed by the thin portion or the penetrating portion are connected to each other. Therefore, since it is possible to reduce the stress generated over the range from the vibrating body to the beam, it is possible to reduce the propagation of a vibration caused by the vibration leakage phenomenon, which propagates to the beam, to the fixing portions.

### APPLICATION EXAMPLE 4

This application example is directed to the vibrator element according to the above-described application example, wherein the vibrating body includes a base portion, first and second detection vibrating arms extending from the base portion to both sides along a first direction, first and second connecting arms extending from the base portion to both the sides along a second direction perpendicular to the first direction, first and second drive vibrating arms extending from the first connecting arm to both the sides along the first direction, and third and fourth drive vibrating arms extending from the second connecting arm to both the sides along the first direction. A detection vibrating system is formed by the first and second detection vibrating arms, and a drive vibrating system is formed by the first to fourth drive vibrating arms. The support portion includes first and second support portions that are disposed so as to face each other along the first direction with the vibrating body interposed therebetween and that extend along the second direction. The beam includes a first beam that passes between the first detection vibrating arm and the first drive vibrating arm to connect the first support portion and the base portion to each other, a second beam that passes between the first detection vibrating arm and the third drive vibrating arm to connect the first support portion and the base portion to each other, a third beam that passes between the second detection vibrating arm and the second drive vibrating arm to connect the second support portion and the base portion to each other, and a fourth beam that passes between the second detection vibrating arm and the fourth drive vibrating arm to connect the second support portion and the base portion to each other.

In the vibrator element according to this application example, the thin portion or the narrow portion is provided between the fixing portion and each of the first to fourth beams. Therefore, since it is possible to reduce the stress generated over the range from the vibrating body to the beam, it is possible to reduce the propagation of a vibration caused by the vibration leakage phenomenon, which propagates to the beam, to the fixing portions. As a result, it is possible to detect the angular velocity while reducing a temperature drift.

### APPLICATION EXAMPLE 5

This application example is directed to the vibrator element according to the above-described application example, wherein a first connection beam formed by connection between the first and second beams and a second connection beam formed by connection between the third and fourth beams are provided, and the vibrating body is connected to the first and second support portions through the first and second connection beams, respectively.

In the vibrator element according to this application example, the vibrating body is connected to each support portion through either the first connection beam or the second connection beam. For this reason, in addition to deformation caused by the thin portion and the narrow portion described above, the junction is easily deformed in various directions. Accordingly, it is possible to further reduce the stress generated over the range from the vibrating body to the connection beam. As a result, it is possible to reduce the propagation of a vibration caused by the vibration leakage phenomenon, which propagates to the connection beam, to the fixing portions.

### APPLICATION EXAMPLE 6

This application example is directed to a vibrating device including: a substrate having at least two connection pads; and the vibrator element according to the above-described application example. The connection pad and the fixing portion are bonded to each other using a conductive fixing member.

In the vibrating device according to this application example, the vibrator element according to the above-described application example is used. Therefore, it is possible to provide a vibrating device capable of reducing the deterioration of the vibration characteristic of the vibrator element, especially, reducing a temperature drift.

### APPLICATION EXAMPLE 7

This application example is directed to the vibrating device according to the above-described application example, wherein a part of a contour of the connection pad and apart of a region, in which the thin portion or the penetrating portion is provided, overlap with each other in plan view of the substrate.

In the vibrating device according to this application example, the thin portion or the penetrating portion can be used as a scale (mark). Therefore, positioning of the vibrator element with respect to the substrate can be performed more accurately and easily.

### APPLICATION EXAMPLE 8

This application example is directed to a physical quantity detecting device including: the vibrator element according to the above-described application example; a drive circuit that drives the vibrator element; and a detection circuit that detects a predetermined physical quantity on the basis of a detection signal from the vibrator element.

According to this application example, the vibrator element according to the above-described application example is used. Therefore, it is possible to provide a physical quantity detecting device whose characteristics are stable, especially, a highly reliable physical quantity detecting device capable of reducing a temperature drift.

### APPLICATION EXAMPLE 9

This application example is directed to an electronic apparatus including the vibrator element according to the above-described application example.

According to this application example, the vibrator element according to the above-described application example is used. Therefore, it is possible to provide an electronic apparatus whose characteristics are stable, especially, a highly reliable electronic apparatus capable of reducing a temperature drift.

### BRIEF DESCRIPTION OF THE DRAWINGS

The invention will be described with reference to the accompanying drawings, wherein like numbers reference like elements.

FIG. 1 is a view (a sectional view and a plan view) showing a vibrating device according to an embodiment of the invention.

FIG. 2 is a plan view of a gyro element as a vibrator element provided in the vibrating device.

FIG. 3 is a plan view of a gyro element as a vibrator element provided in the vibrating device.

FIGS. 4A and 4B are partially enlarged views of the gyro element, where FIG. 4A is a plan view and FIG. 4B is a front view.

FIGS. 5A and 5B are plan views for explaining the driving of the gyro element.

FIG. 6A is a sectional view for explaining an example of the effect of the gyro element according to the present embodiment, and FIG. 6B is a sectional view showing a problem of a gyro element in the related art.

FIGS. 7A to 7F are partial plan views showing modification examples of the gyro element.

FIGS. 8A to 8F are partial plan views showing modification examples of the gyro element.

FIG. 9 is a partial plan view showing other modification examples of the gyro element.

FIG. 10 is a schematic view showing the configuration of a physical quantity detecting device.

### DESCRIPTION OF EXEMPLARY EMBODIMENTS

Hereinafter, a vibrator element and a vibrating device according to embodiments of the invention will be described in detail with reference to the accompanying drawings.

### Embodiments

First, a vibrating device to which a vibrator element according to an embodiment of the invention is applied will be described.

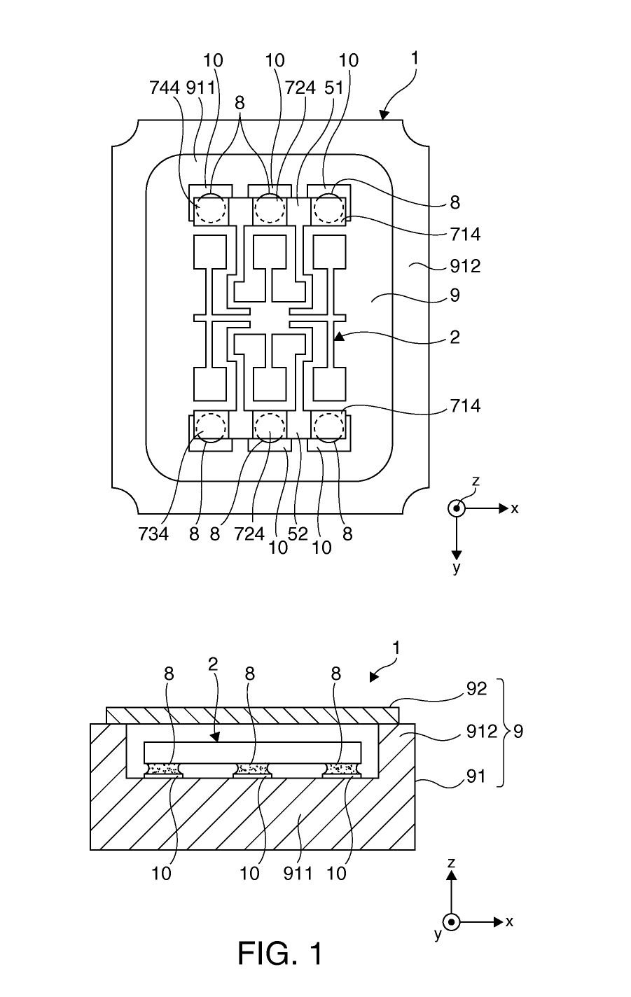

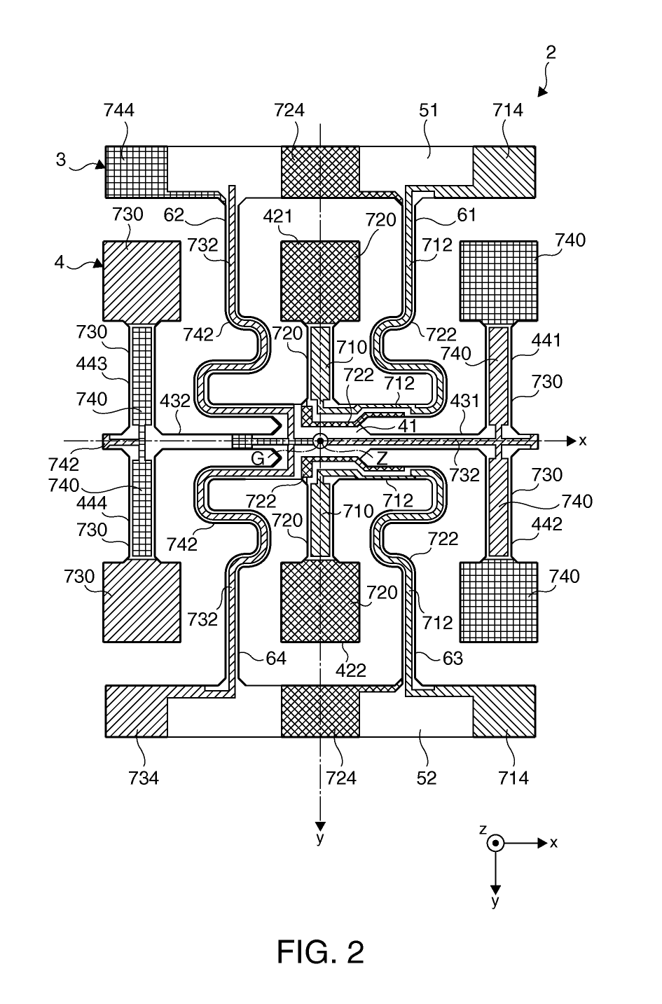

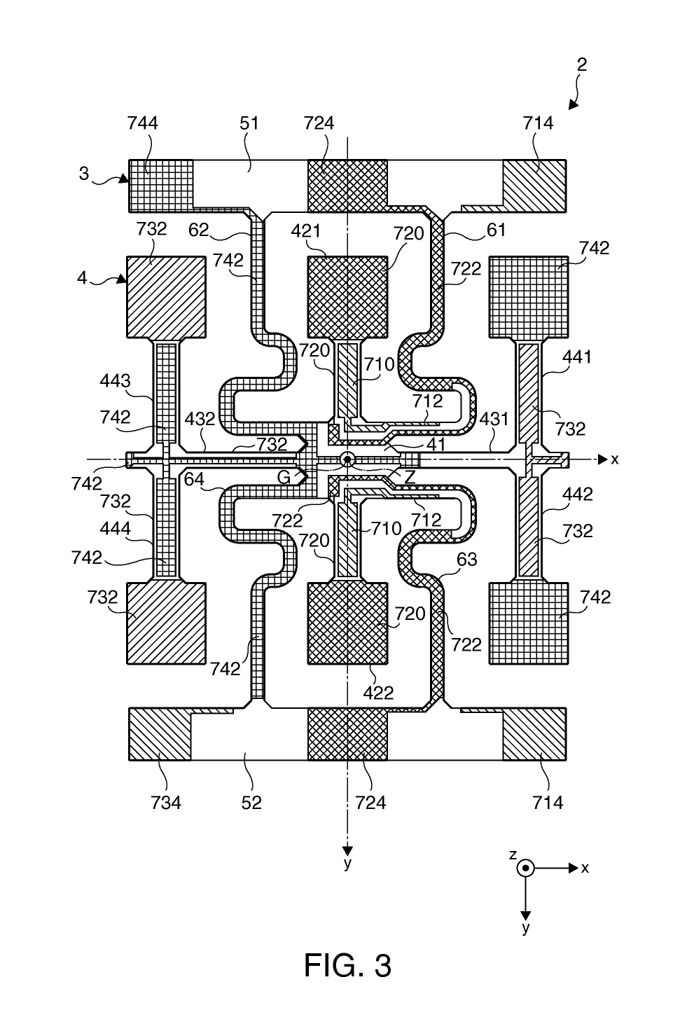

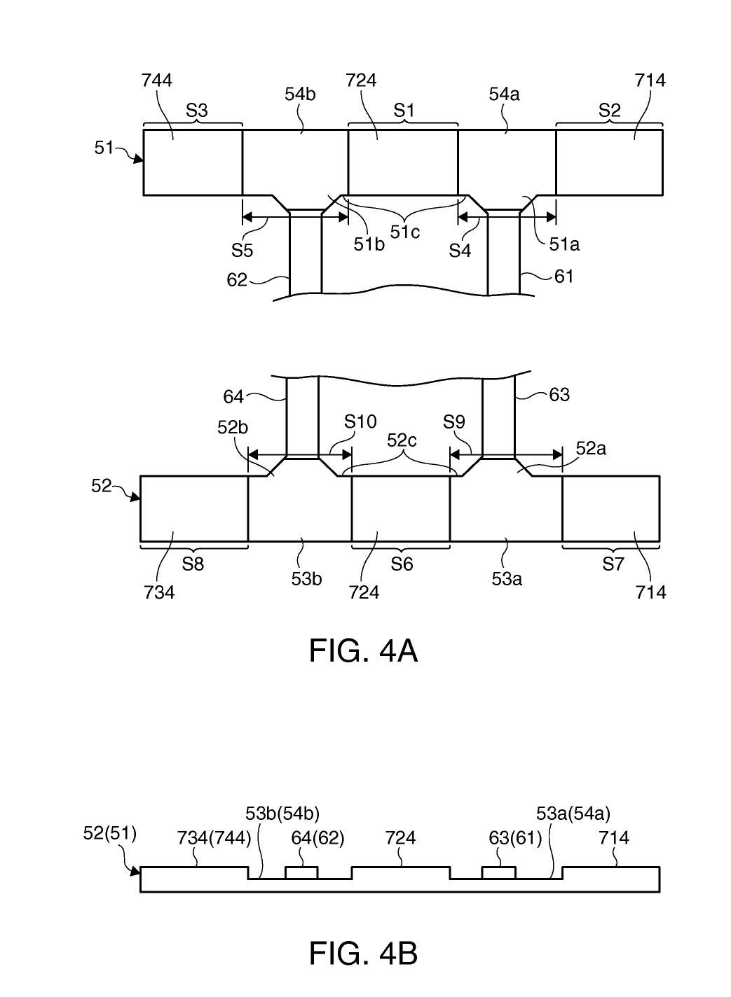

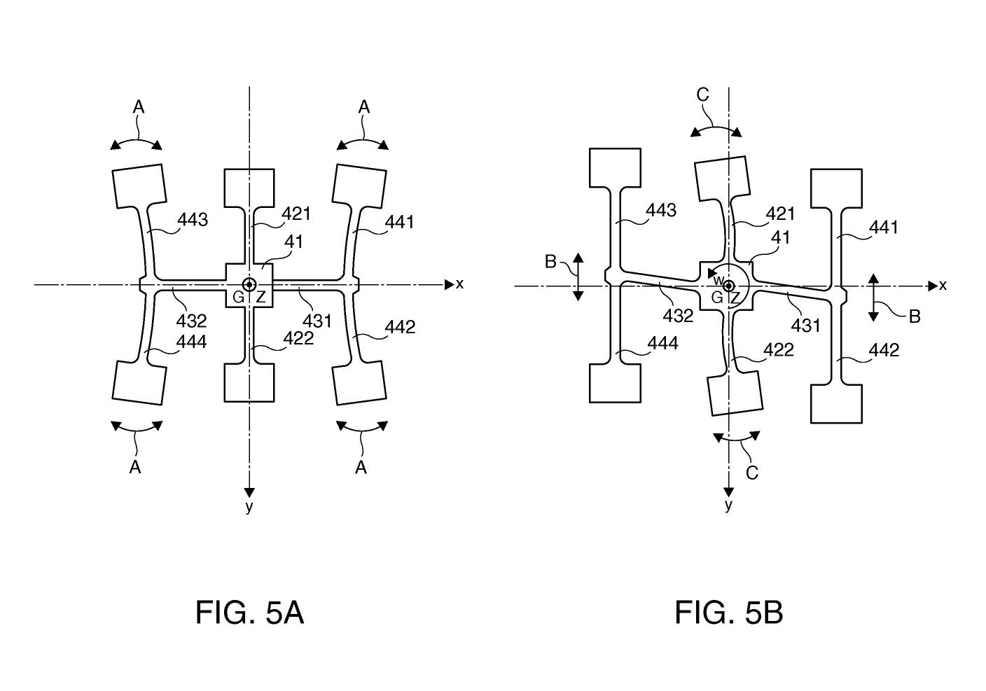

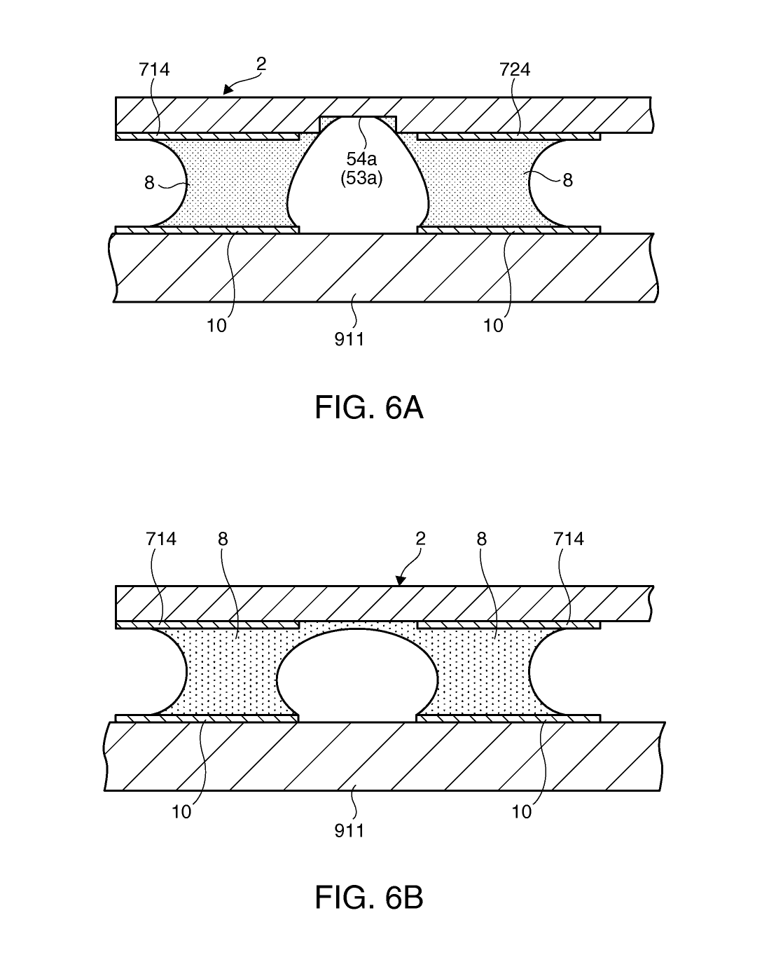

FIG. 1 is a plan view and a front sectional view showing the vibrating device according to the embodiment of the invention. FIGS. 2 and 3 are plan views of a gyro element provided in the vibrating device shown in FIG. 1. FIGS. 4A and 4B are partially enlarged views of the gyro element shown in FIG. 3. FIG. 4A is a plan view, and FIG. 4B is a front view. FIGS. 5A and 5B are plan views for explaining the driving of the gyro element. FIGS. 6A and 6B are views for explaining an example of the effect of the gyro element according to the present embodiment. FIG. 6A is a front sectional view for explaining an example of the effect in the configuration of the present embodiment, and FIG. 6B is a sectional view showing a problem of a gyro element in the related art.

In addition, as shown in FIG. 1, three axes perpendicular to each other are set as an x axis, a y axis, and a z axis hereinbelow, and the z axis matches the thickness direction of the vibrating device. In addition, a direction parallel to the x axis is called an “x-axis direction (second direction)”, a direction parallel to the y axis is called a “y-axis direction (first direction)”, and a direction parallel to the z axis is called a “z-axis direction”.

A vibrating device 1 shown in FIG. 1 has a gyro element (vibrating element) 2 as a vibrator element and a package 9 in which the gyro element 2 is housed. Hereinafter, the gyro element 2 and the package 9 will be described in detail in order.

### Gyro Element

FIG. 2 is a top view of a gyro element when viewed from above (lid 92 side), and FIG. 3 is a bottom view (transparent view) of the gyro element when viewed from above. In addition, in FIGS. 2 and 3, electrodes and terminals are hatched for convenience of explanation. In addition, in FIGS. 2 and 3, electrodes and terminals shown by the same hatching are electrically connected to each other. In addition, in FIGS. 4A and 4B, support portions, beams, electrodes, and the like are not shown for convenience of explanation.

The gyro element 2 is an “in-plane detection type” sensor that detects the angular velocity around the z axis. As shown in FIGS. 2 and 3, the gyro element 2 includes a vibrator element 3 and a plurality of electrodes, wiring lines, and terminals provided on the top surface of the vibrator element 3.

The vibrator element 3 may be formed of piezoelectric materials, such as quartz crystal, lithium tantalate, and lithium niobate. Among these materials, it is preferable to form the vibrator element 3 using quartz crystal. Thus, it is possible to obtain the vibrator element 3 capable of exhibiting the excellent vibration characteristic (frequency characteristic).

Such a vibrator element 3 includes a so-called double T type vibrating body 4, first and second support portions 51 and 52 as support portions that support the vibrating body 4, and first to fourth beams 61, 62, 63, and 64 as beams that connect the vibrating body 4 to the first and second support portions 51 and 52.

The vibrating body 4 extends on the xy plane, and has a thickness in the z-axis direction. Such a vibrating body 4 includes a base portion 41 positioned at the center, first and second detection vibrating arms 421 and 422 extending from the base portion 41 to both sides along the y-axis direction, first and second connecting arms 431 and 432 extending from the base portion 41 to both sides along the x-axis direction, first and second drive vibrating arms 441 and 442 extending from the distal end of the first connecting arm 431 to both sides along the y-axis direction, and third and fourth drive vibrating arms 443 and 444 extending from the distal end of the second connecting arm 432 to both sides along the y-axis direction. In the distal end of each of the first and second detection vibrating arms 421 and 422 and the first to fourth drive vibrating arms 441, 442, 443, and 444, an approximately rectangular weight portion (hammer head) having a larger width than the proximal side is provided. The angular velocity detection sensitivity of the gyro element 2 is improved by providing such a weight portion. In addition, this weight portion is also called a “distal end portion” hereinbelow.

In addition, the first and second drive vibrating arms 441 and 442 may extend from the middle of the first connecting arm 431 in its extending direction. Similarly, the third and fourth drive vibrating arms 443 and 444 may also extend from the middle of the second connecting arm 432 in its extending direction.

In addition, the first and second support portions 51 and 52 extend along the x-axis direction, and the vibrating body 4 is located between the first and second support portions 51 and 52. In other words, the first and second support portions 51 and 52 are disposed so as to face each other along the y-axis direction with the vibrating body 4 interposed therebetween. The first support portion 51 is connected to the base portion 41 through the first and second beams 61 and 62, and the second support portion 52 is connected to the base portion 41 through the third and fourth beams 63 and 64.

The first beam 61 passes between the first detection vibrating arm 421 and the first drive vibrating arm 441 to connect the first support portion 51 and the base portion 41 to each other, the second beam 62 passes between the first detection vibrating arm 421 and the third drive vibrating arm 443 to connect the first support portion 51 and the base portion 41 to each other, the third beam 63 passes between the second detection vibrating arm 422 and the second drive vibrating arm 442 to connect the second support portion 52 and the base portion 41 to each other, and the fourth beam 64 passes between the second detection vibrating arm 422 and the fourth drive vibrating arm 444 to connect the second support portion 52 and the base portion 41 to each other.

Each of the beams 61, 62, 63, and 64 has a meandering portion (S-shaped portion) that extends along the y-axis direction while reciprocating along the x-axis direction, and has elasticity in directions of the x and y axes. In addition, since each of the beams 61, 62, 63, and 64 has a long and narrow shape with a meandering portion, the beams 61, 62, 63, and 64 have elasticity in all directions. Therefore, even if the impact is applied from the outside, it is possible to reduce or suppress detection noise due to the external impact since the beams 61, 62, 63, and 64 serve to absorb the impact.

In the above, the configuration of the vibrator element 3 has been described. As shown in FIGS. 2 and 3, a detection signal electrode 710, a detection signal wiring line 712, a detection signal terminal 714, a detection ground electrode 720, a detection ground wiring line 722, a detection ground terminal 724, a drive signal electrode 730, a drive signal wiring line 732, a drive signal terminal 734, a drive ground electrode 740, a drive ground wiring line 742, and a drive ground terminal 744 are provided in such a vibrator element 3.

In addition, the detection signal terminal 714, the detection ground terminal 724, the drive signal terminal 734, and the drive ground terminal 744 are equivalent to fixing portions.

For the sake of convenience, in FIGS. 2 and 3, the detection signal electrode 710, the detection signal wiring line 712, and the detection signal terminal 714 are indicated by the rightward diagonal lines, the detection ground electrode 720, the detection ground wiring line 722, and the detection ground terminal 724 are cross-hatched, the drive signal electrode 730, the drive signal wiring line 732, and the drive signal terminal 734 are indicated by the leftward diagonal lines, and the drive ground electrode 740, the drive ground wiring line 742, and the drive ground terminal 744 are indicated by horizontal and vertical cross lines. In addition, in FIGS. 2 and 3, electrodes, wiring lines, and terminals provided on the side surface of the vibrator element 3 are indicated by thick lines.

The electrodes 710, 720, 730, and 740, the wiring lines 712, 722, 732, and 742, and the terminals 714, 724, 734, and 744 may be formed to have a structure in which a base layer formed of chromium and an electrode layer formed of gold are laminated, for example. Accordingly, it is possible to form the electrodes 710, 720, 730, and 740, the wiring lines 712, 722, 732, and 742, and the terminals 714, 724, 734, and 744 with good adhesion.

The electrodes 710, 720, 730, and 740 are electrically isolated from each other. Similarly, the wiring lines 712, 722, 732, and 742 are electrically isolated from each other, and the terminals 714, 724, 734, and 744 are electrically isolated from each other. Hereinafter, these electrodes, wiring lines, and terminals will be described in order. In addition, hereinbelow, for convenience of explanation, the surface shown in FIG. 2 is called a “top surface”, the surface shown in FIG. 3 is called a “bottom surface”, and the surface that connects the top and bottom surfaces is called a “side surface”.

### (1) Detection Signal Electrodes, Detection Signal Wiring Lines, and Detection Signal Terminals

The detection signal electrodes 710 are provided on the top and bottom surfaces of the first and second detection vibrating arms 421 and 422. In the present embodiment, however, the detection signal electrode 710 is not provided in the distal ends of the first and second detection vibrating arms 421 and 422. The detection signal electrodes 710 are disposed symmetrically with respect to the xz plane. The detection signal electrodes 710 are electrodes for detecting the distortion of a piezoelectric material caused by vibration when the detection vibration of the first and second detection vibrating arms 421 and 422 is excited.

In addition, the detection signal wiring lines 712 are provided in the first and third beams 61 and 63. More specifically, the detection signal wiring lines 712 are provided on the top surfaces of the first and third beams 61 and 63. In addition, the detection signal wiring lines 712 are also provided on the side surface of a connection portion of the first beam 61 and the first support portion 51, the side surface of a junction between the third beam 63 and the second support portion 52, and the top and bottom surfaces of the base portion 41. Such detection signal wiring lines 712 are disposed symmetrically with respect to the xy plane.

In addition, the detection signal terminals 714 are provided in the first and second support portions 51 and 52. More specifically, the detection signal terminals 714 are provided on the top, bottom, and side surfaces of the first and second support portions 51 and 52. The detection signal terminals 714 provided on the top, bottom, and side surfaces of the first support portion 51 are electrically connected to each other. In addition, the detection signal terminals 714 provided on the top, bottom, and side surfaces of the second support portion 52 are electrically connected to each other.

The detection signal terminal 714 provided in the first support portion 51 is disposed on the negative direction side (a direction opposite to y-axis arrow direction in the drawings) of the y axis with respect to the distal end of the first drive vibrating arm 441 in which the drive ground electrode 740 is provided. That is, the detection signal terminal 714 provided in the first support portion 51 and the drive ground electrode 740 provided in the distal end of the first drive vibrating arm 441 face each other in the y-axis direction. In addition, the detection signal terminal 714 provided in the second support portion 52 is disposed on the positive direction side of the y axis with respect to the distal end of the second drive vibrating arm 442 in which the drive ground electrode 740 is provided. That is, the detection signal terminal 714 provided in the second support portion 52 and the drive ground electrode 740 provided in the distal end of the second drive vibrating arm 442 face each other in the y-axis direction. Such detection signal terminals 714 are disposed symmetrically with respect to the xz plane.

The detection signal terminal (first detection signal terminal) 714 provided in the first support portion 51 is electrically connected to the detection signal electrode (first detection signal electrode) 710 provided in the first detection vibrating arm 421 through the detection signal wiring line 712 provided in the first beam 61. Specifically, the detection signal terminal 714 provided in the first support portion 51 is connected to the detection signal wiring line 712 provided on the top surface of the first beam 61. The detection signal wiring line 712 is connected to the detection signal electrodes 710, which are provided on the top and bottom surfaces of the first detection vibrating arm 421, through the top surface of the first beam 61, the side surface of a junction between the first beam 61 and the base portion 41, and the top and bottom surfaces of the base portion 41. In this manner, a first detection signal generated by the vibration of the first detection vibrating arm 421 can be transmitted from the detection signal electrode 710 to the detection signal terminal 714 provided in the first support portion 51.

The detection signal terminal (second detection signal terminal) 714 provided in the second support portion 52 is electrically connected to the detection signal electrode (second detection signal electrode) 710 provided in the second detection vibrating arm 422 through the detection signal wiring line 712 provided in the third beam 63. Specifically, the detection signal terminal 714 provided in the second support portion 52 is connected to the detection signal wiring line 712 provided on the top surface of the third beam 63. The detection signal wiring line 712 is connected to the detection signal electrodes 710, which are provided on the top and bottom surfaces of the second detection vibrating arm 422, through the top surface of the third beam 63, the side surface of a junction between the third beam 63 and the base portion 41, and the top and bottom surfaces of the base portion 41. In this manner, a second detection signal generated by the vibration of the second detection vibrating arm 422 can be transmitted from the detection signal electrode 710 to the detection signal terminal 714 provided in the second support portion 52.

### (2) Detection Ground Electrodes, Detection Ground Wiring Lines, and Detection Ground Terminals

The detection ground electrodes 720 are provided in the distal ends of the first and second detection vibrating arms 421 and 422. Specifically, the detection ground electrodes 720 are provided on the top and bottom surfaces of the distal ends of the first and second detection vibrating arms 421 and 422. In addition, the detection ground electrodes 720 are provided on the side surfaces of the first and second detection vibrating arms 421 and 422. The detection ground electrodes 720 provided on the top, bottom, and side surfaces of the first detection vibrating arm 421 are electrically connected to each other. In addition, the detection ground electrodes 720 provided on the top, bottom, and side surfaces of the second detection vibrating arm 422 are electrically connected to each other. Such detection ground electrodes 720 are disposed symmetrically with respect to the xz plane. The detection ground electrode 720 has a ground potential with respect to the detection signal electrode 710.

In addition, the detection ground wiring lines 722 are provided in the first and third beams 61 and 63. Specifically, the detection ground wiring lines 722 are provided on the bottom and side surfaces of the first and third beams 61 and 63. In addition, the detection ground wiring lines 722 are provided on the top and bottom surfaces of the base portion 41. The detection ground wiring lines 722 are disposed symmetrically with respect to the xz plane.

In addition, the detection ground terminals 724 are provided in the first and second support portions 51 and 52. Specifically, the detection ground terminals 724 are provided on the top, bottom, and side surfaces of the first and second support portions 51 and 52. The detection ground terminals 724 provided on the top, bottom, and side surfaces of the first support portion 51 are electrically connected to each other. In addition, the detection ground terminals 724 provided on the top, bottom, and side surfaces of the second support portion 52 are electrically connected to each other.

The detection ground terminal 724 provided in the first support portion 51 is disposed on the negative direction side of the y axis with respect to the distal end of the first detection vibrating arm 421 in which the detection ground electrode 720 is provided. That is, the detection ground terminal 724 provided in the first support portion 51 and the detection ground electrode 720 provided in the distal end of the first detection vibrating arm 421 face each other in the y-axis direction. In addition, the detection ground terminal 724 provided in the second support portion 52 is disposed on the positive direction side of the y axis with respect to the distal end of the second detection vibrating arm 422 in which the detection ground electrode 720 is provided. That is, the detection ground terminal 724 provided in the second support portion 52 and the detection ground electrode 720 provided in the distal end of the second detection vibrating arm 422 face each other in the y-axis direction. Such detection ground terminals 724 are disposed symmetrically with respect to the xz plane.

The detection ground terminal (first detection ground terminal) 724 provided in the first support portion 51 is electrically connected to the detection ground electrode (first detection ground electrode) 720, which is provided in the first detection vibrating arm 421, through the detection ground wiring line 722 provided in the first beam 61. Specifically, the detection ground terminal 724 provided in the first support portion 51 is connected to the detection ground wiring lines 722 provided on the bottom and side surfaces of the first beam 61. The detection ground wiring line 722 is connected to the detection ground electrodes 720, which are provided on the top and bottom surfaces of the first detection vibrating arm 421, through the bottom and side surfaces of the first beam 61 and the top and bottom surfaces of the base portion 41.

The detection ground terminal (second detection ground terminal) 724 provided in the second support portion 52 is electrically connected to the detection ground electrode (second detection ground electrode) 720, which is provided in the second detection vibrating arm 422, through the detection ground wiring line 722 provided in the third beam 63. Specifically, the detection ground terminal 724 provided in the second support portion 52 is connected to the detection ground wiring lines 722 provided on the bottom and side surfaces of the third beam 63. The detection ground wiring line 722 is connected to the detection ground electrodes 720, which are provided on the top and bottom surfaces of the second detection vibrating arm 422, through the bottom and side surfaces of the third beam 63 and the top and bottom surfaces of the base portion 41.

The detection signal electrodes 710, the detection signal wiring lines 712, the detection signal terminals 714, the detection ground electrodes 720, the detection ground wiring lines 722, and the detection ground terminals 724 are disposed as described above. In this manner, a detection vibration generated in the first detection vibrating arm 421 can appear as electric charges between the detection signal electrode 710 and the detection ground electrode 720 provided in the first detection vibrating arm 421 and be extracted as a signal from the detection signal terminal 714 and the detection ground terminal 724 provided in the first support portion 51. In addition, a detection vibration generated in the second detection vibrating arm 422 can appear as electric charges between the detection signal electrode 710 and the detection ground electrode 720 provided in the second detection vibrating arm 422 and be extracted as a signal from the detection signal terminal 714 and the detection ground terminal 724 provided in the second support portion 52.

### (3) Drive Signal Electrodes, Drive Signal Wiring Lines, and Drive Signal Terminals

The drive signal electrodes 730 are provided in the first and second drive vibrating arms 441 and 442. In the present embodiment, however, the drive signal electrodes 730 are not provided in the distal ends of the first and second drive vibrating arms 441 and 442. Specifically, the drive signal electrodes 730 are provided on the top and bottom surfaces of the first and second drive vibrating arms 441 and 442.

In addition, the drive signal electrodes 730 are also provided on the side surfaces of the third and fourth drive vibrating arms 443 and 444 and the top and bottom surfaces of the distal ends of the third and fourth drive vibrating arms 443 and 444. The drive signal electrodes 730 provided on the top, bottom, and side surfaces of the third drive vibrating arm 443 are electrically connected to each other. In addition, the drive signal electrodes 730 provided on the top, bottom, and side surfaces of the fourth drive vibrating arm 444 are electrically connected to each other. Such drive signal electrodes 730 are disposed symmetrically with respect to the xz plane. The drive signal electrodes 730 are electrodes for exciting the drive vibration of the first to fourth drive vibrating arms 441, 442, 443, and 444.

The drive signal wiring lines 732 are provided in the second and fourth beams 62 and 64. Specifically, the drive signal wiring lines 732 are provided on the top surfaces of the second and fourth beams 62 and 64. In addition, the drive signal wiring lines 732 are provided on the top surface of the base portion 41, the top surface of the first connecting arm 431, and the side surfaces of the first and second connecting arms 431 and 432. Such drive signal wiring lines 732 are disposed symmetrically with respect to the xz plane.

The drive signal terminal 734 is provided in the second support portion 52. Specifically, the drive signal terminals 734 are provided on the top, bottom, and side surfaces of the second support portion 52. The drive signal terminals 734 provided on the top, bottom, and side surfaces of the second support portion 52 are electrically connected to each other.

The drive signal terminal 734 provided in the second support portion 52 is disposed on the positive direction side of the y axis with respect to the distal end of the fourth drive vibrating arm 444 in which the drive signal electrode 730 is provided. That is, the drive signal terminal 734 provided in the second support portion 52 and the drive signal electrode 730 provided in the distal end of the fourth drive vibrating arm 444 face each other in the y-axis direction.

The drive signal terminal 734 provided in the second support portion 52 is electrically connected to the drive signal electrodes 730, which are provided in the first to fourth drive vibrating arms 441, 442, 443, and 444, through the drive signal wiring line 732 provided in the fourth beam 64. Specifically, the drive signal terminal 734 is connected to the drive signal wiring line 732 provided on the top surface of the fourth beam 64, and the drive signal wiring line 732 is connected to the drive signal electrodes 730, which are provided on the top surfaces of the first and second drive vibrating arms 441 and 442, through the top surface of the fourth beam 64, the top surface of the base portion 41, and the top surface of the first connecting arm 431. In addition, the drive signal wiring line 732 is connected to the drive signal electrodes 730, which are provided on the bottom surfaces of the first and second drive vibrating arms 441 and 442, through the top surface of the first connecting arm 431 and the side surface of the first connecting arm 431. In addition, the drive signal wiring line 732 is connected to the drive signal electrodes 730, which are provided on the top and bottom surfaces of the third and fourth drive vibrating arms 443 and 444, through the top surface of the base portion 41 and the top and side surfaces of the second connecting arm 432. In this manner, drive signals for drive vibration of the first to fourth drive vibrating arms 441, 442, 443, and 444 can be transmitted from the drive signal terminal 734 to the drive signal electrode 730.

### (4) Drive Ground Electrodes, Drive Ground Wiring Lines, and Drive Ground Terminals

The drive ground electrodes 740 are provided in the distal ends of the first and second drive vibrating arms 441 and 442. Specifically, the drive ground electrodes 740 are provided on the top and bottom surfaces of the distal ends of the first and second drive vibrating arms 441 and 442. In addition, the drive ground electrodes 740 are also provided on the side surfaces of the first and second drive vibrating arms 441 and 442. The drive ground electrodes 740 provided on the top, bottom, and side surfaces of the first drive vibrating arm 441 are electrically connected to each other. In addition, the drive ground electrodes 740 provided on the top, bottom, and side surfaces of the second drive vibrating arm 442 are electrically connected to each other.

In addition, the drive ground electrodes 740 are also provided on the top and bottom surfaces of the third and fourth drive vibrating arms 443 and 444. In the present embodiment, however, the drive ground electrodes 740 are not provided in the distal ends of the third and fourth drive vibrating arms 443 and 444. Such drive ground electrodes 740 are disposed symmetrically with respect to the xz plane. The drive ground electrode 740 has a ground potential with respect to the drive signal electrode 730.

In addition, the drive ground wiring lines 742 are provided in the second and fourth beams 62 and 64. Specifically, the drive ground wiring lines 742 are provided on the bottom and side surfaces of the second and fourth beams 62 and 64. In addition, the drive ground wiring lines 742 are provided on the bottom surface of the base portion 41, the side surface of the first connecting arm 431, and the bottom and side surfaces of the second connecting arm 432. Such drive ground wiring lines 742 are disposed symmetrically with respect to the xz plane.

In addition, the drive ground terminals 744 are provided in the first support portion 51. Specifically, the drive ground terminals 744 are provided on the top, bottom, and side surfaces of the first support portion 51. The drive ground terminals 744 provided on the top, bottom, and side surfaces of the first support portion 51 are electrically connected to each other.

The drive ground terminal 744 provided in the first support portion 51 is disposed on the negative direction side of the y axis with respect to the distal end of the third drive vibrating arm 443 in which the drive signal electrode 730 is provided. That is, the drive ground terminal 744 provided in the first support portion 51 and the drive signal electrode 730 provided in the distal end of the third drive vibrating arm 443 face each other in the y-axis direction.

In addition, the drive ground terminal 744 provided in the first support portion 51 is electrically connected to the drive ground electrodes 740, which are provided in the first to fourth drive vibrating arms 441, 442, 443, and 444, through the drive ground wiring line 742 provided in the second beam 62. Specifically, the drive ground terminal 744 is connected to the drive ground wiring lines 742 provided on the bottom and side surfaces of the second beam 62, and the drive ground wiring line 742 is connected to the drive ground electrodes 740, which are provided on the top and bottom surfaces of the first and second drive vibrating arms 441 and 442, through the bottom and side surfaces of the second beam 62, the bottom surface of the base portion 41, and the side surface of the first connecting arm 431. In addition, the drive ground wiring line 742 is connected to the drive ground electrodes 740, which are provided on the top and bottom surfaces of the third and fourth drive vibrating arms 443 and 444, through the bottom surface of the base portion 41 and the bottom and side surfaces of the second connecting arm 432.

As described above, the drive signal electrodes 730, the drive signal wiring lines 732, the drive signal terminals 734, the drive ground electrodes 740, the drive ground wiring lines 742, and the drive ground terminal 744 are disposed. In this manner, electric fields can be generated between the drive signal electrodes 730 and the drive ground electrodes 740, which are provided in the first to fourth drive vibrating arms 441, 442, 443, and 444, by applying drive signals between the drive signal terminal 734 provided in the second support portion 52 and the drive ground terminal 744 provided in the first support portion 51. As a result, it is possible to perform a drive vibration of each of the drive vibrating arms 441, 442, 443, and 444.

In addition, in this example, a configuration has been described in which three terminals of the detection signal terminal 714, the detection ground terminal 724, and the drive ground terminal 744 as fixing portions are provided in the first support portion 51 as one support portion. However, the number of terminals as fixing portions may be 2 or more. In addition, as described above, also in the second support portion 52, the number of terminals as fixing portions may be 2 or more.

(5) A Junction at which a Beam and a Support Portion (Fixing Portion) are Connected

As described above, in the first support portion 51 as a support portion, the detection signal terminal 714, the detection ground terminal 724, and the drive ground terminal 744 as fixing portions are provided along the x-axis direction (direction crossing the extending direction of a beam) so as to be separated from each other. Specifically, as shown in FIG. 4A, the detection ground terminal 724 is provided in the middle (region S1 between a junction 51a of the first support portion 51 and the first beam 61 and a junction 51b of the first support portion 51 and the second beam 62) of the first support portion 51 extending along the x-axis direction, the detection signal terminal 714 is provided in one end (region S2 located on the right side from the junction 51a in FIG. 4A) of the first support portion 51, and the drive ground terminal 744 is provided on the other end (region S3 located on the left side from the junction 51b in FIG. 4A) of the first support portion 51.

On one surface (surface on which a conductive fixing member 8, which will be described later, is applied) of such a first support portion 51, a thin portion 54a that is formed to have a step difference from the one surface is provided between the detection signal terminal 714 and the detection ground terminal 724. In addition, a region S4 where the thin portion 54a is provided includes the junction 51a in the x-axis direction. In addition, an end 51c of the thin portion 54a facing the vibrating body 4 (refer to FIGS. 2 and 3) is opened on the side surface of the first support portion 51.

In addition, on one surface (surface on which the conductive fixing member 8, which will be described later, is applied) of the first support portion 51, a thin portion 54b that is formed to have a step difference from the one surface is provided between the drive ground terminal 744 and the detection ground terminal 724. In addition, a region S5 where the thin portion 54b is provided includes the junction 51b in the x-axis direction. In addition, an end 51c of the thin portion 54b facing the vibrating body 4 (refer to FIGS. 2 and 3) is opened on the side surface of the first support portion 51.

Similarly, in the second support portion 52, the detection signal terminal 714, the detection ground terminal 724, and the drive signal terminal 734 as a fixing portion are provided along the x-axis direction (direction crossing the extending direction of a beam) so as to be separated from each other. Specifically, as shown in FIG. 4A, the detection ground terminal 724 is provided in the middle (region S6 between a junction 52a of the second support portion 52 and the third beam 63 and a junction 52b of the second support portion 52 and the fourth beam 64) of the second support portion 52 extending along the x-axis direction, the detection signal terminal 714 is provided in one end (region S7 located on the right side from the junction 52a in FIG. 4A) of the second support portion 52, and the drive signal terminal 734 is provided on the other end (region S8 located on the left side from the junction 52b in FIG. 4A) of the second support portion 52.

In addition, on one surface (surface on which the conductive fixing member 8, which will be described later, is applied) of the second support portion 52, a thin portion 53a that is formed to have a step difference from the one surface is provided between the detection signal terminal 714 and the detection ground terminal 724. In addition, a region S9 where the thin portion 53a is provided includes the junction 52a in the x-axis direction. In addition, an end 52c of the thin portion 53a facing the vibrating body 4 (refer to FIGS. 2 and 3) is opened on the side surface of the second support portion 52.

In addition, on one surface (surface on which the conductive fixing member 8, which will be described later, is applied) of the second support portion 52, a thin portion 53b that is formed to have a step difference from the one surface is provided between the detection ground terminal 724 and the drive signal terminal 734. In addition, a region S10 where the thin portion 53b is provided includes the junction 52b in the x-axis direction. In addition, an end 52c of the thin portion 53b facing the vibrating body 4 (refer to FIGS. 2 and 3) is opened on the side surface of the second support portion 52.

The gyro element 2 having such a configuration detects the angular velocity ω around the z axis as follows. As shown in FIG. 5A, in the gyro element 2, the drive vibrating arms 441, 442, 443, and 444 perform flexural vibration in a direction indicated by the arrow A when an electric field is generated between the drive signal electrode 730 and the drive ground electrode 740 in a state where the angular velocity ω is not applied. In this case, the first and second drive vibrating arms 441 and 442 and the third and fourth drive vibrating arms 443 and 444 perform a symmetrical vibration with respect to the yz plane passing through the center point G (center of gravity G). Accordingly, the base portion 41, the first and second connecting arms 431 and 432, and the first and second detection vibrating arms 421 and 422 almost do not vibrate.

When the angular velocity ω around the z axis is applied to the gyro element 2 in a state where this drive vibration is performed, a vibration as shown in FIG. 5B occurs. That is, the Coriolis force acts on the drive vibrating arms 441, 442, 443, and 444 and the connecting arms 431 and 432 in a direction of arrow B, and a detection vibration in a direction of arrow C is excited in response to the vibration in the direction of arrow B. Then, the detection signal electrode 710 and the detection ground electrode 720 detect the distortion of the detection vibrating arms 421 and 422 generated by this vibration. As a result, the angular velocity ω is calculated.

### Package

The package 9 houses the gyro element 2 therein. In addition, not only the gyro element 2 but also an IC chip for performing the driving of the gyro element 2 and the like may be housed in the package 9. Such a package 9 has an approximately rectangular shape in plan view (xy plan view).

The package 9 has a base 91, which has a recess opened on the top surface, and a lid 92, which is bonded to the base so as to close the opening of the recess. In addition, the base 91 has a plate-shaped bottom plate 911 and a frame-shaped side wall 912 provided on the periphery of the top surface of the bottom plate 911. Such a package 9 has a housing space S inside, and the gyro element 2 is housed and installed airtight in the housing space S.

The gyro element 2 is fixed to the top surface of the bottom plate 911 through the conductive fixing member 8, such as solder, silver paste, and conductive adhesive (adhesive in which a conductive filler, such as metal particles, is dispersed in a resin material) in the first and second support portions 51 and 52. Since the first and second support portions 51 and 52 are located in both ends of the gyro element 2 in the y-axis direction, the vibrating body 4 of the gyro element 2 is supported in both ends by fixing such the portions to the bottom plate 911. As a result, it is possible to stably fix the gyro element 2 to the bottom plate 911. For this reason, since an unnecessary vibration (vibration other than a vibration to be detected) of the gyro element 2 is suppressed, the detection accuracy of the angular velocity ω by the gyro element 2 is improved.

In addition, six conductive fixing members 8 are provided so as to correspond to (be in contact with) the two detection signal terminals 714, the two detection ground terminals 724, the drive signal terminal 734, and the drive ground terminal 744 provided in the first and second support portions 51 and 52 and so as to be separated from each other. In addition, six connection pads 10 corresponding to the two detection signal terminals 714, the two detection ground terminals 724, the drive signal terminal 734, and the drive ground terminal 744 are provided on the top surface of the bottom plate 911, and each connection pad 10 and each terminal corresponding thereto are electrically connected through the conductive fixing member 8.

Through such a configuration, the conductive fixing member 8 can be used not only as a fixing member for fixing the gyro element 2 to the bottom plate 911 but also as a connection member for electrical connection with the gyro element 2. As a result, it is possible to simplify the configuration of the vibrating device 1.

In addition, the conductive fixing member 8 is also used as a gap member that forms a gap between the gyro element 2 and the bottom plate 911 in order to prevent contact between the gyro element 2 and the bottom plate 911. Accordingly, since it is possible to prevent the destruction or damage of the gyro element 2 due to contact with the bottom plate 911, the vibrating device 1 can detect the angular velocity accurately and have excellent reliability.

In addition, each connection pad 10 is pulled out to the outside of the package 9 through a conductor post (not shown). When an IC chip or the like is housed in the package 9, each connection pad 10 may be electrically connected to the IC chip.

Materials of the base 91 are not particularly limited, and various ceramics, such as aluminum oxide, may be used. In addition, although materials of the lid 92 are not particularly limited, it is preferable to use a member having a linear expansion coefficient similar to that of the material of the base 91. For example, when the above-described ceramic is used as a material of the base 91, it is preferable to use an alloy, such as Kovar. In addition, bonding of the base 91 and the lid 92 is not particularly limited. For example, the base 91 and the lid 92 may be bonded to each other through an adhesive or may be bonded to each other by seam welding or the like.

Here, as described above, the junctions 51a and 51b including the thin portions 54a and 54b are provided in the first support portion 51 of the gyro element 2, and the junctions 52a and 52b including the thin portions 53a and 53b are provided in the second support portion 52. The following effects can be obtained by providing such junctions 51a, 51b, 52a, and 52b.

In the vibrating device 1 described in the present embodiment, the first and second beams 61 and 62 of the used gyro element 2 are connected (bonded) to the junctions 51a and 51b including the thin portions 54a and 54b, respectively, and the third and fourth beams 63 and 64 are connected (bonded) to the junction 52a and 52b, respectively. The thin portions 54a, 54b, 53a, and 53b are formed such that the thickness in the top to bottom direction is small. Accordingly, since the rigidity of the thin portions 54a, 54b, 53a, and 53b is low, deformation easily occurs. Due to this deformation, it is possible to reduce a so-called vibration leakage phenomenon in which a vibration propagating from the vibrating body to the beam is transmitted to the detection signal terminal 714, the detection ground terminal 724, the drive signal terminal 734, and the drive ground terminal 744 as fixing portions. By suppressing this vibration leakage phenomenon, it is possible to reduce the deterioration of the vibration characteristic of a vibrator element, especially, a temperature drift, which may be caused by the vibration leakage phenomenon.

In addition, by providing the thin portions 54a, 54b, 53a, and 53b, it is possible to obtain the following effects in addition to the above-described effects. Hereinafter, this will be described in detail with reference to FIGS. 6A and 6B.

As described above, the gyro element 2 is fixed to the bottom plate 911 through the conductive fixing member 8. Here, in the process of fixing the gyro element 2 to the bottom plate 911, for example, silver paste (conductive fixing member) 8 is applied on each of the six connection pads 10 provided on the bottom plate 911, and the silver paste 8 is fixed by placing the gyro element 2 with its bottom surface toward the bottom plate 911 so that the applied silver paste 8 and corresponding terminals (the detection signal terminal 714, the detection ground terminal 724, the drive signal terminal 734, and the drive ground terminal 744) are in contact with each other and pressing the gyro element 2. As a result, the gyro element 2 is fixed to the bottom plate 911 through the silver paste 8.

For this reason, for example, when the silver paste 8 cannot be accurately applied at a predetermined position, the silver paste 8 spreads when the gyro element 2 is pressed, as shown in FIG. 6B, in a known gyro element (gyro element in which the thin portions 54a, 54b, 53a, and 53b are not provided). As a result, the silver pastes 8 thus spread come in contact with each other, and this may cause short circuit therebetween. In terms of the accuracy of the device, there is a certain amount of variation in the application position or the amount of application of the silver paste 8. For this reason, the above-described problem occurs relatively easily. In the gyro element 2 of the present embodiment, therefore, the occurrence of such a problem is prevented by providing the thin portions 54a, 54b, 53a, and 53b in the first and second support portions 51 and 52. Hereinafter, specific explanation will be given. Since the operations and effects of the thin portions 54a, 54b, 53a, and 53b are the same, the thin portion 54a will be representatively described.

As shown in FIG. 6A, each silver paste 8 corresponding to the detection ground terminal 724 and the detection signal terminal 714 is spread by pressing the gyro element 2. In this case, even if the application position of the silver paste 8 corresponding to the detection ground terminal 724 is biased toward the detection signal terminal 714, the spread silver paste 8 stops at the stepped corner of the thin portion 54a due to the surface tension of the stepped corner and spread to the middle is suppressed. For this reason, it is difficult for the silver paste 8 to reach the vicinity of the middle of the thin portion 54a. In this manner, it is possible to prevent contact of the silver pastes 8 adjacent to each other.

In addition, due to the stepped corner of the thin portion 54a facing the vibrating body 4, flow of the silver paste 8 accumulated in the thin portion 54a to the vibrating body 4 side is prevented. As a result, since contact between the silver paste 8 and wiring lines provided in the first beam 61 is prevented, it is possible to prevent the occurrence of short circuit between the silver paste 8 and the wiring lines.

In addition, as described above, an end of the thin portion 54a not facing the vibrating body is opened on the side surface of the first support portion 51. Therefore, since the detection ground terminal 724 and the detection signal terminal 714 are clearly divided by the step difference of the thin portion 54a, it is possible to prevent contact of the silver pastes 8 through a region where the thin portion 54a is not provided, for example. In this manner, it is possible to reliably prevent contact of the silver pastes 8.

In addition, the material of the gyro element 2 (vibrator element 3) is different from the material of the bottom plate 911. Accordingly, when the temperature of the vibrating device 1 rises, stress is generated in the vibrator element 3 through the conductive fixing member 8 due to the difference in thermal expansion coefficient. Specifically, stress to extend the first and second support portions 51 and 52 in the x-axis direction is applied when the thermal expansion coefficient of the bottom plate 911 is greater than that of the vibrator element 3, and stress to contract the first and second support portions 51 and 52 in the x-axis direction is applied when the thermal expansion coefficient of the bottom plate 911 is smaller than that of the vibrator element 3. Since such stress can be absorbed or reduced due to the region S4 provided in the thin portion 54a, it is possible to suppress the unwanted distortion of the gyro element 2. As a result, it is possible to prevent a reduction in the detection accuracy of the gyro element 2.

In addition, it is preferable that the contour of the connection pad 10 overlap a part of the region S4 where the thin portion 54a is provided in xy plan view. In this manner, since the thin portion 54a can be used as a scale (mark), positioning of the gyro element 2 (vibrator element 3) with respect to the bottom plate 911 can be performed more accurately.

### MODIFICATION EXAMPLES

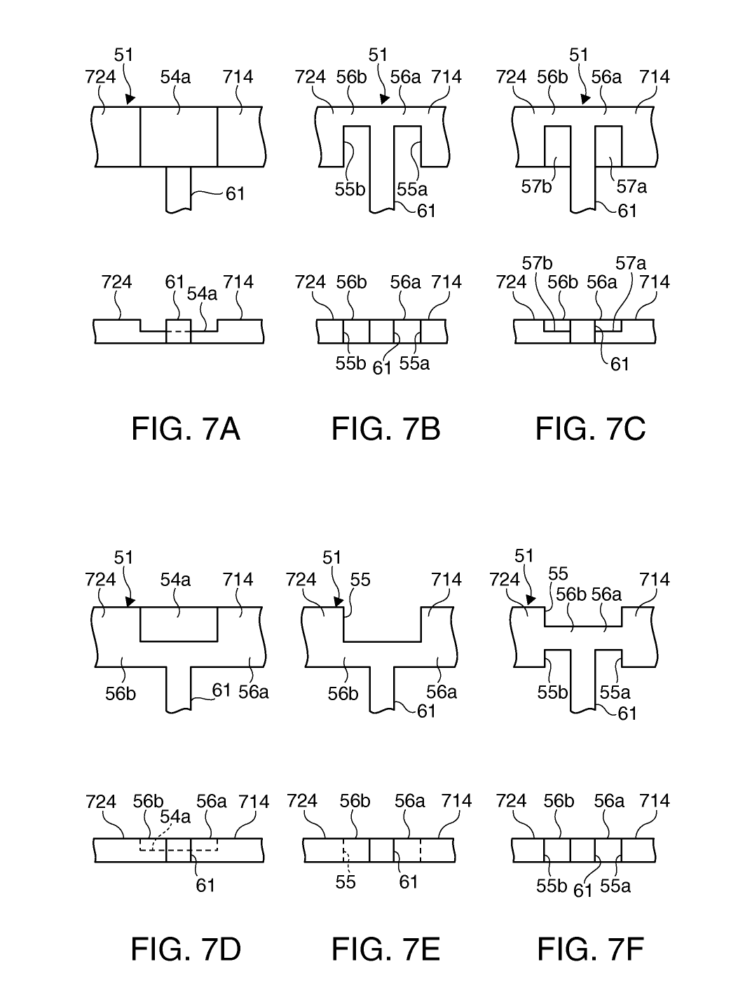

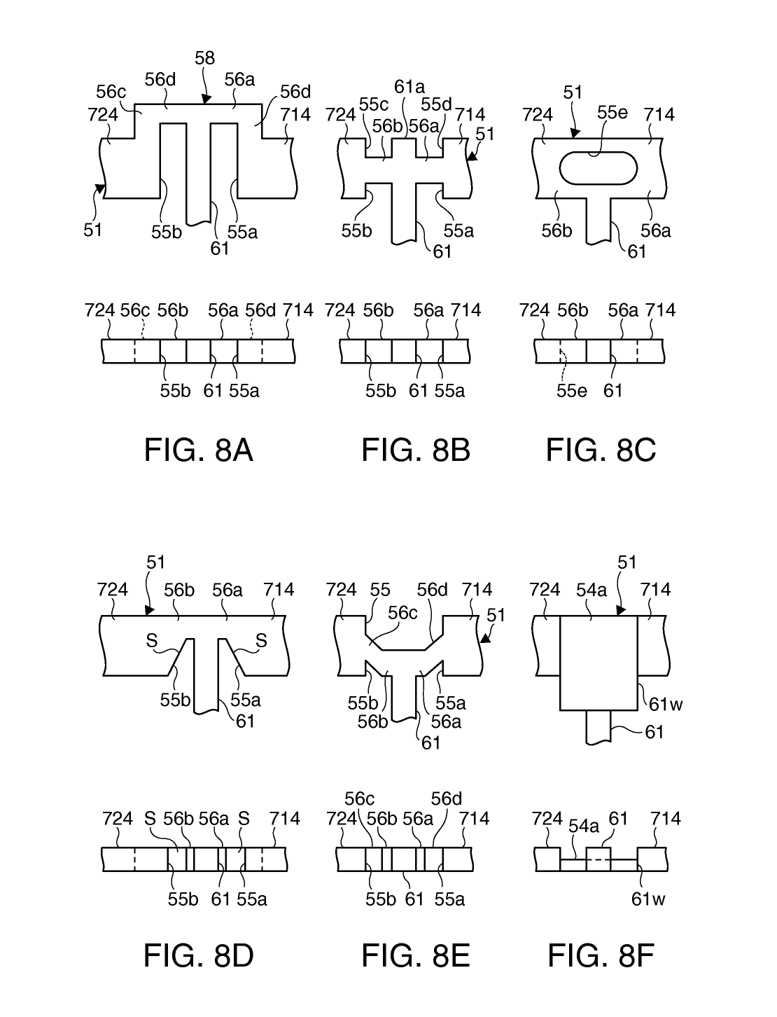

Next, modification examples of a connection portion between a beam and a support portion in the above embodiment will be described using FIGS. 7A to 7F and 8A to 8F. FIGS. 7A to 7F and 8A to 8F are partial plan views showing modification examples of the gyro element.

In addition, specific explanation will be given hereinafter. Since the operations and effects of a connection portion between each beam and a support portion are the same, the connection portion between the first beam 61 and the first support portion 51 (refer to FIGS. 4A and 4B) will be representatively described. In addition, the effects of each modification example will be representatively described in first and second modification examples. In third to twelfth modification examples, the same effects described in the first and second modification examples will be omitted.

### First Modification Example

In a first modification example shown in FIG. 7A, the first beam 61 and the thin portion 54a provided between the detection signal terminal 714 and the detection ground terminal 724 of the first support portion 51 are connected to each other. In other words, the first beam 61, the detection signal terminal 714, and the detection ground terminal 724 are provided so as to extend through the thin portion 54a. In addition, an end of the thin portion 54a facing the vibrating body 4 (refer to FIGS. 2 and 3) is opened on the side surface of the first support portion 51.

In the configuration of the first modification example, deformation easily occurs since the rigidity of the thin portion 54a is low as in the embodiment described above. Therefore, it is possible to reduce the vibration leakage phenomenon in which a vibration propagating from the vibrating body to the beam is transmitted to the detection signal terminal 714 and the detection ground terminal 724. By suppressing this vibration leakage phenomenon, it is possible to have the same effects as in the embodiment described above.

### Second Modification Example

In a second modification example shown in FIG. 7B, penetrating portions 55a and 55b formed by removing the first support portion 51 so as to be penetrated in the top to bottom direction are provided.

The penetrating portions 55a and 55b are provided on both sides of the first beam 61. One end of each of the penetrating portions 55a and 55b is opened on the side surface of the first support portion 51 facing the vibrating body 4 (refer to FIGS. 2 and 3), and the other end has a notched shape having a side surface in the first support portion 51. By the penetrating portions 55a and 55b, narrow portions 56a and 56b are formed in the first support portion 51. In addition, the detection signal terminal 714 and the first beam 61 are connected to each other through the narrow portion 56a formed by the penetrating portion 55a, and the detection ground terminal 724 and the first beam 61 are connected to each other through the narrow portion 56b formed by the penetrating portion 55b.

In the configuration of the second modification example, the detection signal terminal 714 and the detection ground terminal 724 are connected to the first beam 61 through the narrow portions 56a and 56b, respectively. Similar to the thin portion 54a described above, since the rigidity of each of the narrow portions 56a and 56b is low, deformation easily occurs. Therefore, it is possible to reduce the vibration leakage phenomenon in which a vibration propagating from the vibrating body to the beam is transmitted to the detection signal terminal 714 and the detection ground terminal 724. By suppressing this vibration leakage phenomenon, it is possible to have the same effects as in the embodiment described above.

### Third Modification Example

In a third modification example shown in FIG. 7C, thin portions 57a and 57b have step differences since portions corresponding to the penetrating portions 55a and 55b provided in the second modification example described above are not penetrated and removed.

The thin portions 57a and 57b are provided on both sides of the first beam 61. One end of each of the thin portions 57a and 57b is opened on the side surface of the first support portion 51 facing the vibrating body 4 (refer to FIGS. 2 and 3), and the other end has a stepped side surface in the first support portion 51. By the thin portions 57a and 57b, narrow portions 56a and 56b are formed in the first support portion 51. In addition, the detection signal terminal 714 and the first beam 61 are connected to each other through the thin portion 57a and narrow portion 56a, and the detection ground terminal 724 and the first beam 61 are connected to each other through the thin portion 57b and narrow portion 56b.

### Fourth Modification Example

In a fourth modification example shown in FIG. 7D, a thin portion 54a is provided in which one end is opened on the opposite side surface to the side surface of the first support portion 51 where the first support portion 51 and the first beam 61 are connected to each other and the other end is formed by a step difference having a side surface in the first support portion 51.

By providing the thin portion 54a, the narrow portions 56a and 56b are formed in the first support portion 51. In addition, the detection signal terminal 714 and the first beam 61 are connected to each other through the narrow portion 56a and the thin portion 54a, and the detection ground terminal 724 and the first beam 61 are connected to each other through the narrow portion 56b and the thin portion 54a.

### Fifth Modification Example

In a fifth modification example shown in FIG. 7E, a penetrating portion 55 is provided in which a portion corresponding to the thin portion 54a provided in the fourth modification example described above is penetrated and removed.

In the penetrating portion 55, one end is opened on the opposite side surface to the side surface of the first support portion 51 where the first support portion 51 and the first beam 61 are connected to each other and the other end has a notched shape having a side surface in the first support portion 51. By providing the penetrating portion 55, the narrow portions 56a and 56b are formed in the first support portion 51. In addition, the detection signal terminal 714 and the first beam 61 are connected to each other through the narrow portion 56a, and the detection ground terminal 724 and the first beam 61 are connected to each other through the narrow portion 56b.

### Sixth Modification Example

In a sixth modification example shown in FIG. 7F, penetrating portions 55a and 55b are formed on both sides of the first beam 61 by removing the first support portion 51 so as to be penetrated in the top to bottom direction, and a penetrating portion 55 is provided on the opposite side to the side where the penetrating portions 55a and 55b are provided.

The penetrating portions 55a and 55b are provided with the first beam 61 interposed therebetween. One end of each of the penetrating portions 55a and 55b is opened on the side surface of the first support portion 51 facing the vibrating body 4 (refer to FIGS. 2 and 3), and the other end has a notched shape having a side surface in the first support portion 51. In the penetrating portion 55, one end is opened on the opposite side surface to the side surface of the first support portion 51 where the first support portion 51 and the first beam 61 face each other, and the other end has a notched shape having a side surface in the first support portion 51. By the penetrating portions 55, 55a, and 55b, narrow portions 56a and 56b are formed in the first support portion 51. In addition, the detection signal terminal 714 and the first beam 61 are connected to each other through the narrow portion 56a, and the detection ground terminal 724 and the first beam 61 are connected to each other through the narrow portion 56b.

### Seventh Modification Example

In a seventh modification example shown in FIG. 8A, a protruding portion 58 is formed in the first support portion 51 on the opposite side to the side where the first support portion 51 and the first beam 61 face each other, and the first beam 61 and the penetrating portions 55a and 55b provided on both sides of the first beam 61 are formed from the protruding portion 58.

The penetrating portions 55a and 55b are provided on both sides of the first beam 61. One end of each of the penetrating portions 55a and 55b is opened on the side surface of the first support portion 51 facing the vibrating body 4 (refer to FIGS. 2 and 3), and the other end has a notched shape having a side surface in the protruding portion 58. In other words, the penetrating portions 55a and 55b are formed to be longer than the width of the first support portion 51. By the penetrating portions 55a and 55b, narrow portions 56a and 56b are formed in the protruding portion 58. In addition, narrow portions 56c and 56d extending from the narrow portions 56a and 56b to the first support portion 51 are formed. In addition, the detection signal terminal 714 and the first beam 61 are connected to each other through the narrow portions 56a and 56d, and the detection ground terminal 724 and the first beam 61 are connected to each other through the narrow portions 56b and 56c.

In this configuration, since narrow portions are long as in the narrow portions 56a and 56d or the narrow portions 56b and 56c, deformation occurs more easily. Therefore, the effects of reduction of vibration leakage and stress relaxation are improved.

### Eighth Modification Example

In an eighth modification example shown in FIG. 8B, the first beam 61, the penetrating portions 55a and 55b provided on both sides of the first beam 61, and penetrating portions 55c and 55d provided in the first support portion 51 on the opposite side to the side where the penetrating portions 55a and 55b are provided, are provided.

The penetrating portions 55c and 55d are provided on both sides of a protruding portion 61a extending from the first beam 61. By the penetrating portions 55a, 55b, 55c, and 55d, narrow portions 56a and 56b are formed. In addition, the detection signal terminal 714 and the first beam 61 are connected to each other through the narrow portion 56a, and the detection ground terminal 724 and the first beam 61 are connected to each other through the narrow portion 56b.

### Ninth Modification Example

In a ninth modification example shown in FIG. 8C, a track-shaped penetrating portion 55e that is a through hole is formed in the first support portion 51.

The penetrating portion 55e is provided so as to face a portion at which the first support portion 51 and the first beam 61 are connected, and one side surface of the penetrating portion 55e forms one side surface of each of the narrow portions 56a and 56b. The narrow portions 56a and 56b are provided on both sides of the first beam 61, the detection signal terminal 714 and the first beam 61 are connected to each other through the narrow portion 56a, and the detection ground terminal 724 and the first beam 61 are connected to each other through narrow portion 56b.

In addition, the shape of the through hole (penetrating portion 55e) is not limited to the track shape, and any shape, such as an elliptical shape, a circular shape, or a shape in which these through holes are arranged in parallel, is possible as long as the narrow portions 56a and 56b can be provided.

### Tenth Modification Example

The configuration of a tenth modification example shown in FIG. 8D is the same as that of the second modification example described above, and the penetrating portions 55a and 55b formed by removing the first support portion 51 so as to be penetrated in the top to bottom direction are provided. However, the shapes of the penetrating portions 55a and 55b are different from those in the second modification example described above.

The penetrating portions 55a and 55b are provided on both sides of the first beam 61. One end of each of the penetrating portions 55a and 55b is opened on the side surface of the first support portion 51 facing the vibrating body 4 (refer to FIGS. 2 and 3), and the other end has a notched shape having a side surface in the first support portion 51. In this case, each of the penetrating portions 55a and 55b has a shape in which the length of the side surface on the other end side is smaller than the length of the open one end, that is, a shape spreading gradually toward the one end (open end) that is opened on the side surface of the first support portion 51. In other words, one side S that forms each of the penetrating portions 55a and 55b is not parallel to the side surface of the first beam 61 facing the one side S but is gradually separated toward the open end. By the penetrating portions 55a and 55b, narrow portions 56a and 56b are formed in the first support portion 51. In addition, the detection signal terminal 714 and the first beam 61 are connected to each other through the narrow portion 56a formed by the penetrating portion 55a, and the detection ground terminal 724 and the first beam 61 are connected to each other through the narrow portion 56b formed by the penetrating portion 55b.

### Eleventh Modification Example

In an eleventh modification example shown in FIG. 8E, similar to the sixth modification example described above, the penetrating portions 55a and 55b formed by removing the first support portion 51 so as to be penetrated in the top to bottom direction are provided on both sides of the first beam 61, and the penetrating portion 55 is provided on the opposite side to the side where the penetrating portions 55a and 55b are provided. The eleventh modification example is different from the sixth modification example described above in that the narrow portions 56a and 56b are not straight but bent.

The penetrating portions 55a and 55b are provided with the first beam 61 interposed therebetween. One end of each of the penetrating portions 55a and 55b is opened on the side surface of the first support portion 51 facing vibrating body 4 (refer to FIGS. 2 and 3), and the other end has a notched shape having a side surface in the first support portion 51. In the penetrating portion 55, one end is opened on the opposite side surface to the side surface of the first support portion 51 where the first support portion 51 and the first beam 61 face each other, and the other end has a notched shape having a side surface in the first support portion 51. By the penetrating portions 55, 55a, and 55b, narrow portions 56a, 56b, 56c, and 56d that are bent to extend are formed in the first support portion 51. In addition, the detection signal terminal 714 and the first beam 61 are connected to each other through the narrow portions 56a and 56d, and the detection ground terminal 724 and the first beam 61 are connected to each other through the narrow portions 56b and 56c.

### Twelfth Modification Example

In a twelfth modification example shown in FIG. 8F, a protruding portion 61w is formed in the first support portion 51 on the side where the first support portion 51 and the first beam 61 are connected to each other, and a thin portion 54a that extends so as to include the protruding portion 61w is formed.

The first beam 61 is connected to the first support portion 51 on one end of the protruding portion 61w extending from the first support portion 51. Accordingly, the thickness of the first beam 61 is larger than the thickness of the thin portion 54a.

### Other Modification Examples

In addition, although the configuration in which each beam of the first to fourth beams 61, 62, 63, and 64 is connected to the first support portion 51 or the second support portion 52 has been described, the following configuration may also be adopted without being limited to the above configuration.

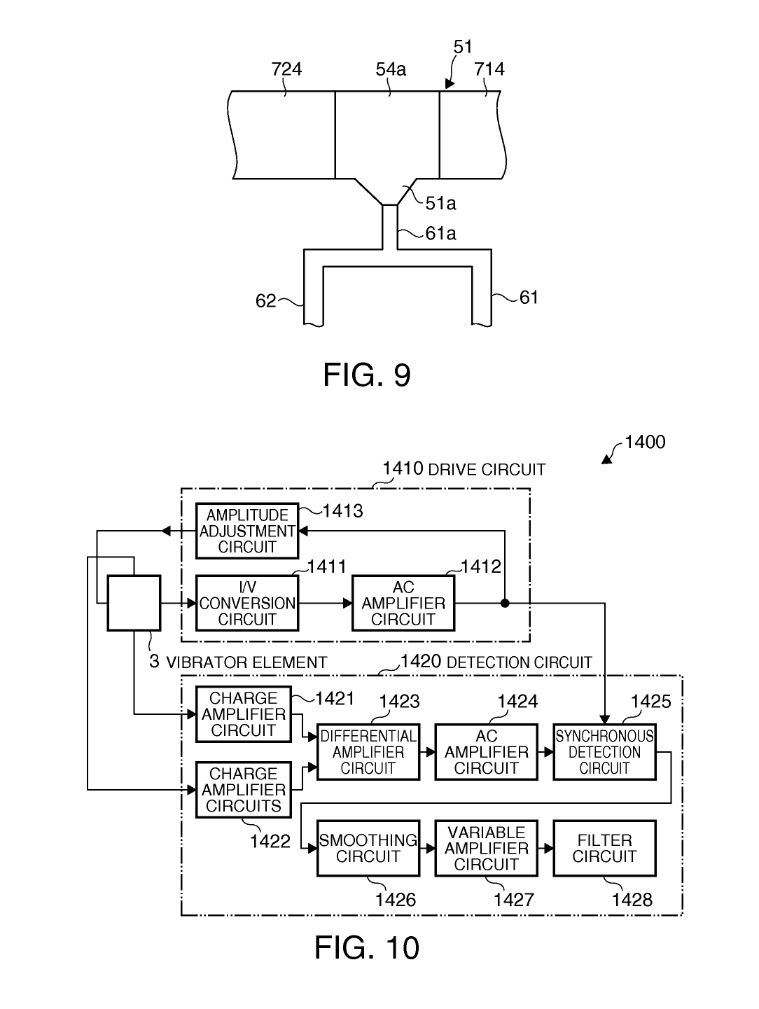

This modification example will be described using FIG. 9. FIG. 9 is a partial plan view showing this modification example. In the configuration of this modification example, first and second beams 61 and 62 are connected to each other while reaching the first support portion 51, thereby forming a first connection beam 61a. The first connection beam 61a is connected to a junction 51a of the first support portion 51. In addition, although not shown, the same configuration may be adopted for third and fourth beams on the second support portion side facing the first support portion. Specifically, the third and fourth beams are connected to each other while reaching the second support portion, thereby forming a second connection beam. The second connection beam is connected to the second support portion.

According to this configuration, since a beam is more flexible (deformed more easily) by providing the first connection beam 61a or the second connection beam, it is possible to further improve the stress relaxation effect and the vibration leakage prevention effect.

Although the above explanation has been given using the gyro element 2 as an example of a vibrator element, applications to the following vibrator elements may also be made without being limited to the gyro element 2. As other vibrator elements, applications to elements for physical quantity measurement, such as an acceleration measuring element, a pressure detection element, and a temperature detection element, may be made.

### Physical Quantity Detecting Device

The above-described vibrating device 1 can be applied to physical quantity detecting devices, such as an angular velocity detecting device, an acceleration detecting device, and a pressure measuring device.

Next, a physical quantity detecting device according to the present embodiment will be described with reference to the accompanying drawings. FIG. 10 is a schematic view showing the configuration of the physical quantity detecting device.

A physical quantity detecting device 1400 shown in FIG. 10 includes a vibrator element according to the embodiment of the invention. In the present embodiment, an example using the vibrator element 3 as the vibrator element according to the embodiment of the invention will be described. Hereinafter, in the physical quantity detecting device 1400 according to the present embodiment, members having the same functions as the members of the vibrator element 3 according to the present embodiment are denoted by the same reference numerals, and detailed explanation thereof will be omitted.

As shown in FIG. 10, the physical quantity detecting device 1400 includes the vibrator element 3, a drive circuit 1410, and a detection circuit 1420. The drive circuit 1410 and the detection circuit 1420 may be included in an IC chip (not shown in FIG. 10).

The drive circuit 1410 functions as a drive circuit according to the invention, and may have an I/V conversion circuit (current-voltage conversion circuit) 1411, an AC amplifier circuit 1412, and an amplitude adjustment circuit 1413. The drive circuit 1410 is a circuit that supplies a drive signal to the drive signal electrode 730 formed in the vibrator element 3. Hereinafter, the drive circuit 1410 will be described in detail.

When the vibrator element 3 vibrates, AC current based on the piezoelectric effect is output from the drive signal electrode 730 formed in the vibrator element 3 and is then input to the I/V conversion circuit 1411 through the drive signal terminal 734. The I/V conversion circuit 1411 converts the input AC current into an AC voltage signal with the same frequency as the vibration frequency of the vibrator element 3 and outputs the AC voltage signal.

The AC voltage signal output from the I/V conversion circuit 1411 is input to the AC amplifier circuit 1412. The AC amplifier circuit 1412 amplifies and outputs the input AC voltage signal.

The AC voltage signal output from the AC amplifier circuit 1412 is input to the amplitude adjustment circuit 1413. The amplitude adjustment circuit 1413 controls the gain to maintain the amplitude of the input AC voltage signal at the fixed value, and outputs the AC voltage signal after gain control to the drive signal electrode 730 through the drive signal terminal 734 formed in the vibrator element 3. The vibrator element 3 vibrates due to the AC voltage signal (drive signal) input to the drive signal electrode 730.

The detection circuit 1420 functions as a detection circuit according to the invention, and may have charge amplifier circuits 1421 and 1422, a differential amplifier circuit 1423, an AC amplifier circuit 1424, a synchronous detection circuit 1425, a smoothing circuit 1426, a variable amplifier circuit 1427, and a filter circuit 1428. The detection circuit 1420 is a circuit that generates a differential amplified signal by differential amplification of a first detection signal, which is generated in the detection signal electrode 710 formed in the first detection vibrating arm 421 of the vibrator element 3, and a second detection signal, which is generated in the detection signal electrode 710 formed in the second detection vibrating arm 422, and detects a predetermined physical quantity on the basis of the differential amplified signal. Hereinafter, the detection circuit 1420 will be described in detail.

Detection signals (AC currents) with opposite phases detected by the detection signal electrode 710 formed in the detection vibrating arms 421 and 422 of the vibrator element 3 are input to the charge amplifier circuits 1421 and 1422 through the detection signal terminal 734. For example, a first detection signal detected by the detection signal electrode 710 formed in the first detection vibrating arm 421 is input to the charge amplifier circuit 1421, and a second detection signal detected by the detection signal electrode 710 formed in the second detection vibrating arm 422 is input to the charge amplifier circuit 1422. In addition, the charge amplifier circuits 1421 and 1422 convert the input detection signals (AC currents) into AC voltage signals having a reference voltage Vref in the middle.

The differential amplifier circuit 1423 generates a differential amplified signal by differential amplification of the output signal of the charge amplifier circuit 1421 and the output signal of the charge amplifier circuit 1422. The output signal (differential amplified signal) of the differential amplifier circuit 1423 is further amplified by the AC amplifier circuit 1424.

The synchronous detection circuit 1425 functions as a detector circuit according to the invention, and extracts an angular velocity component by performing synchronous detection of the output signal of the AC amplifier circuit 1424 on the basis of the AC voltage signal output from the AC amplifier circuit 1412 of the drive circuit 1410.

The angular velocity component signal extracted by the synchronous detection circuit 1425 is smoothed to become a DC voltage signal by the smoothing circuit 1426, and this DC voltage signal is input to the variable amplifier circuit 1427.

The variable amplifier circuit 1427 changes angular velocity sensitivity by amplifying (attenuating) the output signal (DC voltage signal) of the smoothing circuit 1426 with a set gain (or an attenuation rate). The signal amplified (or attenuated) by the variable amplifier circuit 1427 is input to the filter circuit 1428.

The filter circuit 1428 removes a high-frequency noise component from the output signal of the variable amplifier circuit 1427 (more accurately, attenuates the output signal of the variable amplifier circuit 1427 to a predetermined level or lower), and generates a detection signal having a polarity and a voltage level corresponding to the direction and size of the angular velocity. Then, this detection signal is output from an external output terminal (not shown) to the outside.

As described above, according to the physical quantity detecting device 1400, the detection circuit 1420 can generate a differential amplified signal by differential amplification of the first detection signal, which is generated in the detection signal electrode 710 formed in the first detection vibrating arm 421, and the second detection signal, which is generated in the detection signal electrode 710 formed in the second detection vibrating arm 422, and detect a predetermined physical quantity on the basis of the differential amplified signal. In addition, when the impact is applied in the Y-axis direction from the outside, the vibrator element 3 can maintain the amount of change in the electrostatic coupling between a detection signal and a drive signal (almost) equally on the positive and negative direction sides of the Y axis. That is, since the amount of change in the electrostatic coupling between the first detection signal and the drive signal and the amount of change in the electrostatic coupling between the second detection signal and the drive signal can be equalized, it is possible to eliminate the influence of the impact in the Y-axis direction. Therefore, it is possible to provide the physical quantity detecting device 1400 capable of detecting a detection signal stably even if the impact is applied from the outside, especially, in the Y-axis direction.

### Electronic Apparatus

In addition, the vibrating device 1 described above may be provided in various kinds of electronic apparatuses. Examples of the electronic apparatus according to the embodiment of the invention in which the vibrating device 1 is provided are not particularly limited. A personal computer (for example, a mobile personal computer), a mobile terminal such as a mobile phone, a digital still camera, an ink jet type discharge apparatus (for example, an ink jet printer), a laptop personal computer, a tablet personal computer, a television, a video camera, a video tape recorder, a car navigation system, a pager, an electronic diary (electronic diary with a communication function is also included), an electronic dictionary, an electronic calculator, an electronic game machine, a controller for games, a word processor, a workstation, a video phone, a television monitor for security, electronic binoculars, a POS terminal, medical equipment (for example, an electronic thermometer, a sphygmomanometer, a blood glucose meter, and an electrocardiogram measuring device, an ultrasonic diagnostic apparatus, and an electronic oendoscope), a fishfinder, various measuring apparatuses, instruments (for example, instruments in vehicles, aircrafts, and ships), a flight simulator, a head-mounted display, a motion tracer, a motion tracking device, a motion controller, a PDR (measurement of position and direction of pedestrian), and the like may be mentioned.

While the vibrator elements and the vibrating device according to the embodiment of the invention and the modification examples that are shown in the drawings have been described, the invention is not limited to these, and the configuration of each portion may be replaced with an arbitrary configuration having the same function. In addition, other arbitrary structures or processes may be added. In addition, the vibrating device according to the embodiment of the invention may be formed by combining two or more arbitrary configurations (characteristics) in the above-described embodiment and modification examples.

The entire disclosure of Japanese Patent Application No. 2012-016390, filed Jan. 30, 2012 is expressly incorporated by reference herein.

What is claimed is:

1. A vibrator element comprising:
a vibrating body;
a support portion that is connected to a beam extending from the vibrating body and that supports the vibrating body; and
at least two fixing portions that are provided in the support portion and that are arranged in parallel so as to be separated from each other along a direction crossing an extending direction of the beam,
wherein the beam and the support portion are connected between the two fixing portions, and
a thin portion formed to have a thickness in a top to bottom direction of the support portion, which is smaller than a thickness of a portion in which the fixing portions of the support portion are provided, or a penetrating portion, which is formed by removing the support portion so as to be penetrated in the top to bottom direction, is provided between the two fixing portions.

2. The vibrator element according to claim 1,
wherein the support portion includes a narrow portion which extends from the beam to each of the two fixing portions and in which a width of the support portion is smaller than a width of the portion in which the fixing portions of the support portion are provided.

3. The vibrator element according to claim 1,
wherein an end of the thin portion or the penetrating portion facing the vibrating body is opened on a side surface of the support portion.

4. The vibrator element according to claim 1,
wherein the vibrating body includes a base portion, first and second detection vibrating arms extending from the base portion to both sides along a first direction, first and second connecting arms extending from the base portion to both the sides along a second direction perpendicular to the first direction, first and second drive vibrating arms extending from the first connecting arm to both the sides along the first direction, and third and fourth drive vibrating arms extending from the second connecting arm to both the sides along the first direction,
a detection vibrating system is formed by the first and second detection vibrating arms, and a drive vibrating system is formed by the first to fourth drive vibrating arms,
the support portion includes first and second support portions that are disposed so as to face each other along the first direction with the vibrating body interposed therebetween and that extend along the second direction, and
the beam includes a first beam that passes between the first detection vibrating arm and the first drive vibrating arm to connect the first support portion and the base portion to each other, a second beam that passes between the first detection vibrating arm and the third drive vibrating arm to connect the first support portion and the base portion to each other, a third beam that passes between the second detection vibrating arm and the second drive vibrating arm to connect the second support portion and the base portion to each other, and a fourth beam that passes between the second detection vibrating arm and the fourth drive vibrating arm to connect the second support portion and the base portion to each other.

5. The vibrator element according to claim 4,
wherein a first connection beam formed by connection between the first and second beams and a second connection beam formed by connection between the third and fourth beams are provided, and
the vibrating body is connected to the first and second support portions, which are disposed so as to face each other, through the first and second connection beams, respectively.

6. A vibrating device comprising:
a substrate having at least two connection pads; and
the vibrator element according to claim 1,
wherein the connection pad and the fixing portion are bonded to each other using a conductive fixing member.

7. A vibrating device comprising:
a substrate having at least two connection pads; and
the vibrator element according to claim 2,
wherein the connection pad and the fixing portion are bonded to each other using a conductive fixing member.

8. A vibrating device comprising:
a substrate having at least two connection pads; and
the vibrator element according to claim 3,
wherein the connection pad and the fixing portion are bonded to each other using a conductive fixing member.

9. A vibrating device comprising:
a substrate having at least two connection pads; and
the vibrator element according to claim 4,
wherein the connection pad and the fixing portion are bonded to each other using a conductive fixing member.

10. A vibrating device comprising:
a substrate having at least two connection pads; and
the vibrator element according to claim 5,
wherein the connection pad and the fixing portion are bonded to each other using a conductive fixing member.

11. The vibrating device according to claim 6,
wherein a part of a contour of the connection pad and apart of a region, in which the thin portion or the penetrating portion is provided, overlap each other in plan view of the substrate.

12. The vibrating device according to claim 7,
wherein a part of a contour of the connection pad and apart of a region, in which the thin portion or the penetrating portion is provided, overlap each other in plan view of the substrate.

13. The vibrating device according to claim 8,
wherein a part of a contour of the connection pad and apart of a region, in which the thin portion or the penetrating portion is provided, overlap each other in plan view of the substrate.

14. A physical quantity detecting device comprising:
the vibrator element according to claim 4;
a drive circuit that drives the vibrator element; and
a detection circuit that detects a predetermined physical quantity on the basis of a detection signal from the vibrator element.

15. A physical quantity detecting device comprising:
the vibrator element according to claim 5;
a drive circuit that drives the vibrator element; and
a detection circuit that detects a predetermined physical quantity on the basis of a detection signal from the vibrator element.

16. An electronic apparatus comprising the vibrator element according to claim 1.

17. An electronic apparatus comprising the vibrator element according to claim 2.

18. An electronic apparatus comprising the vibrator element according to claim 3.

19. An electronic apparatus comprising the vibrator element according to claim 4.

20. An electronic apparatus comprising the vibrator element according to claim 5.
